(19) United States
(12) Patent Application Publication
(10) Pub. No.: US 2004/0101980 A1
(43) Pub. Date: May 27, 2004

(54) Method for making ferroelectric thin film

(75) Inventors: Kenichi Kurokawa, Suwa-shi (JP); Eiji Natori, Chino-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 10/396,566

(22) Filed: Mar. 26, 2003

(30) Foreign Application Priority Data
Mar. 28, 2002 (JP) 2002-093161

(51) Int. Cl. H01L 21/00; H01L 21/31; H01L 21/469

(52) U.S. Cl. 438/3; 438/778; 438/782

(57) ABSTRACT

A ferroelectric thin film comprising at least two stock solutions is made so that the stock solutions are mixed homogeneously in the plane and over the thickness on a substrate, or so that the stock solutions are mixed having a distribution in the plane and over the thickness on the substrate. A ferroelectric thin film mixed homogeneously in the plane is made by discharging two stock solutions 105 and 106 separately at a fixed discharging rate by separate inkjet heads using an inkjet apparatus having at least two inkjet heads, and a ferroelectric thin film mixed homogeneously over the thickness is made by repeating this process. Moreover, a ferroelectric thin film having a distribution of the stock solutions is made by changing the discharging rate in the thickness direction or the in-plane direction.

### TECHNICAL FIELD

The present invention relates to ceramic thin films used in ferroelectric devices, piezoelectric devices, and the like. In particular, the present invention relates to a method for making ceramic thin films using at least two stock solutions.

### BACKGROUND ART

When a ferroelectric solution and a paraelectric solution are used as stock solutions in the formation of a ferroelectric thin film, these stock solutions are preliminarily mixed so that the mixed solution can be applied to a surface as a homogeneous mixture by spin coating or dipping, which are typical known film formation methods. However, use of the mixed solution causes several problems. Because the shelf life of the solution is short in general, the mixed solution cannot be stored for a long time. For the same reason, an excess amount of unused mixed solution incurs waste of the material.

As disclosed in Japanese Unexamined Patent Application Publication No. 5-235268, a uniform concentration of elements is achieved over the film thickness after firing. In the above-mentioned Japanese Unexamined Patent Application Publication, when the stock solutions are composed of ferroelectric solutions which have different composition ratios, each solution is coated by spin coating as follows: the concentration of an element which readily diffuses from the surface of the ferroelectric thin film increases over the thickness. Unfortunately, many kinds of solutions having different element concentrations are needed to achieve improved homogeneity by spin coating. Furthermore, after the process for making a ferroelectric capacitor, the properties of the ferroelectric capacitor in a plane are uneven due to the in-plane distribution of the temperature during the firing process. Another disadvantage in spin coating is that the distribution of the stock solution composition cannot be varied in the plane direction.

The present invention solves such problems. It is an object of the present invention to provide a ferroelectric thin film made by homogeneously mixing a ferroelectric solution and a paraelectric solution in a plane and over the thickness, furthermore the solutions are mixed during application. It is another object of the present invention to provide a ferroelectric thin film that has a uniform concentration across the film thickness after firing, by applying, as continuously as possible, a minimum number of ferroelectric stock solutions having composition ratios that are different from each other. It is another object of the present invention to provide a ferroelectric thin film that has a reduced in-plane distribution of characteristics of the ferroelectric capacitor after the fabrication process by estimating the in-plane distribution of the characteristics of the ferroelectric capacitor occurring during the fabrication process.

### DISCLOSURE OF INVENTION

(1) A method for making a ferroelectric thin film in accordance with the present invention is characterized in that the ferroelectric thin film is made by discharging at least two stock solutions by an inkjetting process through separate inkjet heads of an apparatus having at least two inkjet heads to apply the stock solutions. According to this method, a superior ferroelectric thin film is provided in which at least two stock solutions are uniformly mixed and deposited in the plane, and by repeating the process, uniform deposition over the film thickness is also achieved.

(2) A method for making a ferroelectric thin film in accordance with the present invention is characterized in that the stock solutions are a ferroelectric solution and a paraelectric solution. According to this method, the solutions are mixed during application of the ferroelectric solution and the paraelectric solution on a substrate at the same time, thus preventing the material deterioration due to a short shelf life of the mixed solution and material waste in cases where an excess amount of the solutions are mixed.

(3) A method for making a ferroelectric thin film in accordance with the present invention is characterized in that the stock solutions are ferroelectric solutions having different composition ratios. In order to deposit ferroelectric solutions with different composition ratios over the film thickness, at least two stock solutions having different concentrations must be prepared in spin coating or dipping however, according to this method, in inkjetting, it is only needed to adjust the discharge amount of each stock solution separately, resulting in high flexibility of composition ratios and relatively easy deposition.

(4) A method for making a ferroelectric thin film in accordance with the present invention is characterized in that the discharge amount of each of the stock solutions is changed to generate a distribution of the composition over the thickness of the thin film. According to this method, the discharge amounts of the stock solutions are changed so that the concentration of an element that readily diffuses outwards among the elements in the stock solutions increases outwards to restrain uneven compositional distribution in the ferroelectric thin film, resulting in a satisfactory hysteresis curve.

(5) A method for making a ferroelectric thin film in accordance with the present invention is characterized in that the discharge amount of each of the stock solutions is changed to generate a distribution of the composition in a plane. According to this method, by estimating in advance uneven in-plane ferroelectric capacitor characteristics resulting from the fabrication steps, and also by varying the in-plane composition during the application of the ferroelectric solution, a ferroelectric thin film with less uneven ferroelectric capacitor characteristics is advantageously provided after the fabrication steps.

(6) A method for making a ferroelectric thin film in accordance with the present invention is characterized in that, in claim 1, a hydrophilic treatment is performed on a substrate before the application of the stock solutions with the inkjetting process.

(7) A method for making a ferroelectric thin film in accordance with the present invention is characterized in that, in claim 1, a discharging time interval in the inkjetting process is set so that a next landing of the stock solutions discharged by inkjetting occurs sufficiently earlier than drying of the previous landing. According to these two methods, at least two stock solutions are uniformly mixed in a liquid state, because the stock solutions discharged by inkjetting on the substrate spread, and next discharge and landing of the stock solutions occurs before the previous discharge and landing of the stock solutions has dried.

(8) A method for making a ferroelectric thin film in accordance with the present invention is characterized in that, in claim 1, a water-repelling treatment is performed on a substrate before applying the stock solutions with the inkjetting process.

(9) A method for making a ferroelectric thin film in accordance with the present invention is characterized in that, in claim 1, a discharging time interval in the inkjetting process is set so that a next landing of the stock solutions discharged by inkjetting occurs after the previous landing of the stock solutions has completely dried. According to these two methods, at least two stock solutions are uniformly mixed in dots, because the stock solutions first discharged by inkjetting and landing on the substrate do not spread, and the next landing of the stock solutions occurs only after the previous landing of the stock solutions has sufficiently dried.

(10) A method for making a ferroelectric thin film in accordance with the present invention is characterized in that the ferroelectric solution and the paraelectric solution are applied so as to each have a distribution in the ferroelectric thin film. According to this method, the formation of a 90-degree domain is prevented, thus attaining a highly rectangular hysteresis curve.

### BRIEF DESCRIPTION OF THE DRAWINGS

FIG. 1 is a schematic perpendicular cross section of a ferroelectric capacitor in a ferroelectric device.

FIG. 2 is a flow chart for making the ferroelectric capacitor of the present invention.

FIG. 3 includes partly enlarged views of a horizontal cross-section and a perpendicular cross-section of the ferroelectric thin film in FIG. 1, deposited by applying droplets regularly in lines by inkjetting.

FIG. 4 includes partly enlarged views of a horizontal cross-section and a perpendicular cross-section of the ferroelectric thin film in FIG. 1, deposited by applying droplets regularly in dots by inkjetting.

FIG. 5 includes partly enlarged views of a horizontal cross-section and a perpendicular cross-section of the ferroelectric thin film in FIG. 1, deposited by applying droplets completely at random by inkjetting.

FIG. 6 is a graph showing hysteresis curves according to Example 1.

FIG. 7 is a graph showing hysteresis curves according to Example 2.

FIG. 8 is a graph showing hysteresis curves of Sample E according to Example 3.

FIG. 9 is a graph showing hysteresis curves of Sample F according to Example 3.

### BEST MODE FOR CARRYING OUT THE INVENTION

Preferred embodiments of the method for making the ferroelectric device of the present invention will be described with reference to the attached drawings.

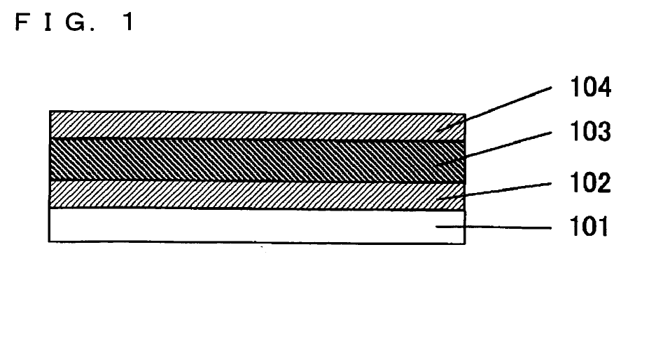

FIG. 1 is a schematic perpendicular cross-section of a ferroelectric capacitor in a ferroelectric device including a silicon substrate 101 with silicon oxide, a lower electrode 102, a ferroelectric thin film 103, and an upper electrode 104. A titanium (Ti) film or a titanium oxide (TiOₓ) film may be deposited on the silicon substrate with silicon oxide.

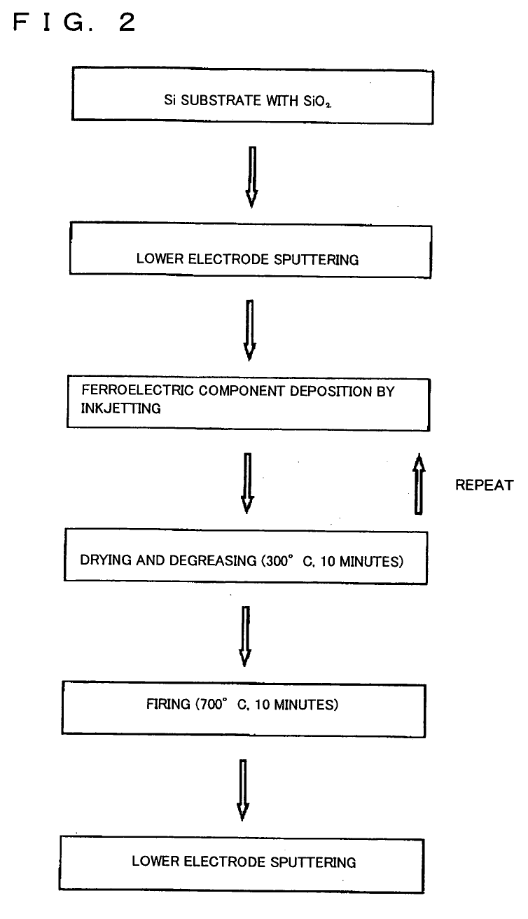

FIG. 2 is a flow chart for making the ferroelectric thin film by inkjetting to make the ferroelectric capacitor. The lower electrode 102 is deposited on the silicon substrate 101 with silicon oxide by sputtering. Then the ferroelectric thin film 103 is applied on the substrate by inkjetting and the product is then dried and degreased on a hotplate at 300° C. for 10 minutes. The processes from “ferroelectric component deposition by inkjetting” to “drying and degreasing” are repeated until the film thickness reaches a desired value. Then, the product is placed in a furnace heated at 700° C. to crystallize the ferroelectric thin film. Finally, the upper electrode 104 is deposited on the substrate by sputtering.

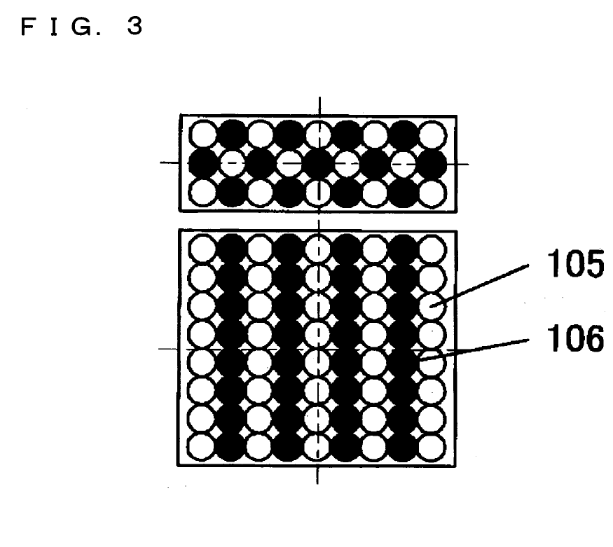

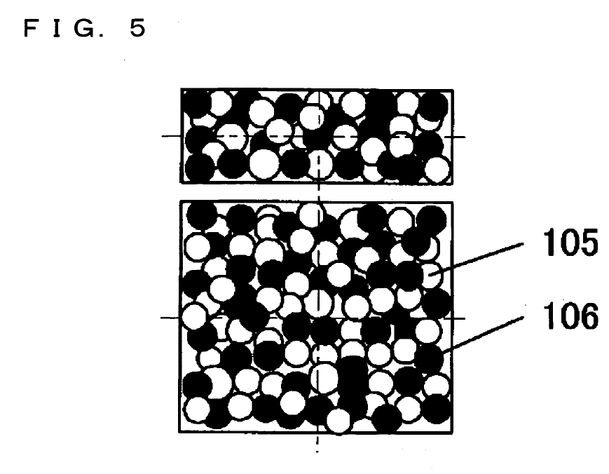

FIGS. 3, 4, and 5 are partly enlarged views of a horizontal cross-section and a perpendicular cross-section of the ferroelectric thin film by applying at least two stock solutions on the substrate by inkjetting. As shown in FIGS. 3, 4, and 5, by controlling the operation of the inkjet head and the discharging operation of each nozzle, different kinds of stock solutions can be mixed in different ways: applying each droplet regularly in lines, applying each droplet regularly in dots, and applying each droplet completely at random.

### EXAMPLE 1

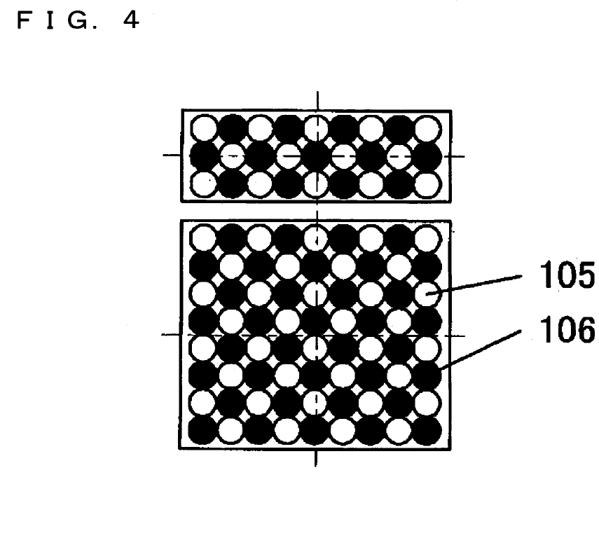

An example in which a solution containing lead zirconate titanate (Pb(Zr,Ti)O₃, hereinafter referred to as PZT), a ferroelectric material and a solution containing bismuth silicate (Bi₂SiOₓ), paraelectric material, were used as stock solutions is described. First, a silicon substrate was thermally oxidized to form silicon oxide thereon, and then iridium (Ir) and iridium oxide (IrOₓ) were deposited by sputtering and reactive sputtering, respectively. Then, as a hydrophilic treatment to improve the wettabilities of the landing solutions, before depositing the ferroelectric thin film, the substrate was pre-baked on a hotplate at 180° C. for one minute and then cooled at room temperature for one minute. Then, the PZT solution and the bismuth silicate solution were applied regularly in dots, as shown in FIG. 4, with separate inkjet heads of an inkjet apparatus. The discharge time interval of each stock solution by the inkjet apparatus was set so that the next landing occurred before the previous landing had dried completely. A cycle including five successive applications was repeated five times to form a film thickness of 100 nm after firing. After each cycle was completed, drying and degreasing were performed on the hotplate. Finally, iridium (Ir) was deposited as an upper electrode through a metal mask by sputtering. The product was referred to as Sample A.

Sample B and Sample C were made to compare with Sample A. In making Sample B, to reduce the wettabilities of the landing solutions, the pre-baking process before depositing the ferroelectric thin film was omitted, and the discharge time interval of each stock solution by the inkjet apparatus was set so that the next landing occurred after the previous landing had completely dried. In making Sample C, the PZT solution and the bismuth silicate solution were premixed and the premixed solution was spin-coated, followed by firing. The thickness of the thin film was 100 nm. In Sample B and Sample C, the conditions except for the above-mentioned process were identical to that of Sample A. Since the solutions in Sample C were mixed immediately before application, the extent of the material deterioration due to the shelf lives was the same as that of Samples A-and B.

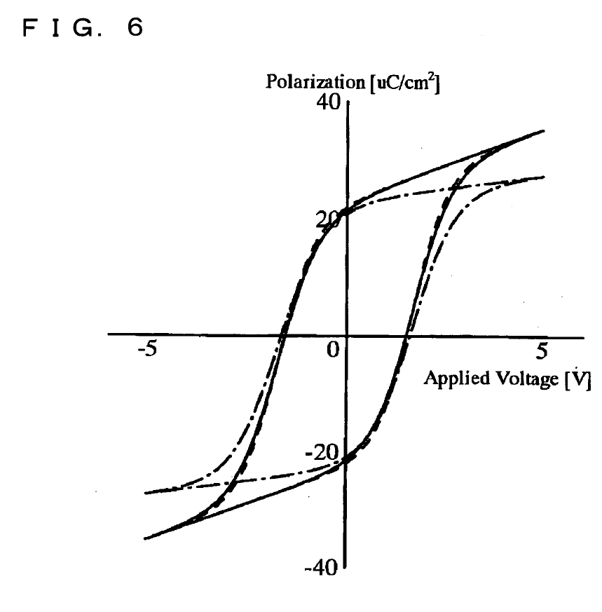

As an electrical characteristic of the ferroelectric components, the hysteresis was measured in these three samples. FIG. 6 is a graph of hysteresis curves of these samples, wherein the solid line, the chain line, and the dotted line indicate Sample A, Sample B, and Sample C, respectively.

Referring to these hysteresis curves, the characteristic of Sample A, which was deposited by inkjetting, was substantially the same as that of Sample C, which was made by spin coating. However, in cases where the mixed solution was allowed to stand for an extended period until the extent of the material deterioration due to the short shelf life was noticeable, the inkjetting process was advantageous.

In addition, a better rectangular hysteresis loop was obtained in Sample B, which was made by mixing the PZT solution and the bismuth silicate solution by inkjetting in the form of dots and in which each component was distributed in the ferroelectric thin film, compared with Sample A, which was made by mixing the solutions in the form of solution.

### EXAMPLE 2

An example in which two PZT solutions (composition ratio: Pb/Zr/Ti=120/35/65 and 110/35/65) were used as the ferroelectric material is described. Hereinafter the PZT solution having the composition Pb/Zr/Ti=120/35/65 and the PZT solution having the composition Pb/Zr/Ti=110/35/65 are referred to as Solution X and Solution Y, respectively. At first, a lower electrode was deposited on a substrate, and then the substrate was pre-baked on a hotplate and was cooled, as in Example 1. Then Solution X and Solution Y were applied regularly in lines, as shown in FIG. 3, with separate inkjet heads of an inkjet apparatus. The discharge time intervals of Solution X and Solution Y by the inkjet apparatus were set so that the next landing occurred a sufficient of time before the previous landing had dried. A cycle including five continuous applications was repeated six times to form a film thickness of 120 nm after firing. The discharge ratio of Solution X to Solution Y (Solution X/Solution Y) was set so that the discharge ratio of Solution X to Solution Y increased with an increase in thickness: the discharge ratio was 0/100 at the first cycle, 20/80 at the second cycle, 40/60 at the third cycle, 60/40 at the fourth cycle, 80/20 at the fifth cycle, and 100/0 at the sixth cycle. After each cycle, drying and degreasing were performed on a hotplate. Finally, the upper electrode was deposited as in Example 1. The product was referred to as Sample D.

To compare with this sample, Sample E was made by applying a PZT solution having a composition ratio of Pb/Zr/Ti=115/35/65 (hereinafter, referred to as Solution Z) by inkjetting, and by repeating a cycle of five successive applications six times to form a film thickness of 120 nm after firing. The conditions except for the above-mentioned process were entirely the same as those of Sample D. Sample D and Sample E contained the same total amounts of Pb immediately after the application.

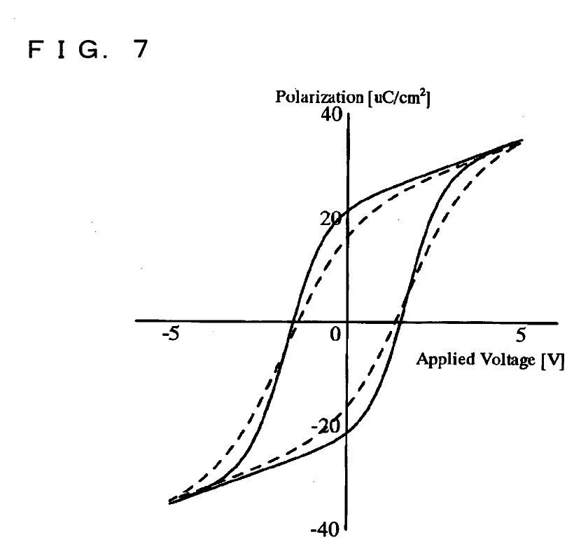

As an electrical characteristic of the ferroelectric components, the hysteresis was measured in the two samples. FIG. 7 is a graph of hysteresis curves of these samples, wherein the solid line and the dotted line show Sample D and Sample E, respectively. Referring to the hysteresis curves, the characteristic of Sample D, which was made by depositing Solution X and Solution Y, is superior to that of Sample E, which was made by depositing only Solution Z. Each sample included the same total amount of the Pb immediately after the application and both samples were made by the same process except that Sample D had a Pb distribution across the thickness. Thus, it was found that a superior hysteresis characteristic was obtained by applying the solutions such that, as the film thickness increased, the Pb concentration became higher rather than the Pb concentration being uniform over the thickness.

Making a thin film including a variable composition ratio in a single-layer unit by spin coating or dipping with general PZT solutions requires the adjustment of each solution concentration. However, such thin film can be made relatively readily by inkjetting. This is because the discharging rate of the PZT solutions (Solution X/Solution Y) can be changed in the inkjetting process by reducing the size of the droplets or extending the discharge intervals. Therefore, thin films having any composition ratio from Solution X to Solution Y can be made with only two solutions, i.e. Solution X and Solution Y.

### EXAMPLE 3

The hysteresis characteristic of Sample E in Example 2 and Sample F having a distribution of Solution X and Solution Y in Example 2 were measured at five random points. Sample E was used to examine the in-plane distribution of the ferroelectric capacitor, and Sample F was used to feed back the in-plane distribution in the thermal process among the entire process. It is noted that Sample F did not have a distribution of Solution X and Solution Y over the thickness, and the fabrication conditions of Sample F were identical to that of Sample E except for the deposition condition of the ferroelectric thin film.

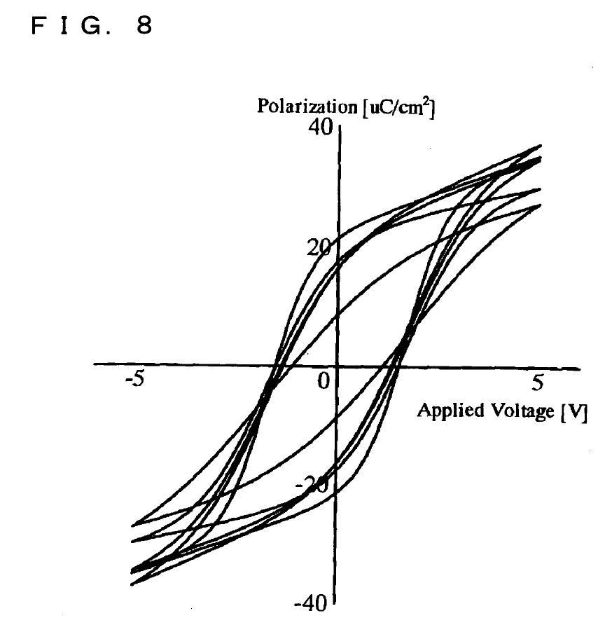

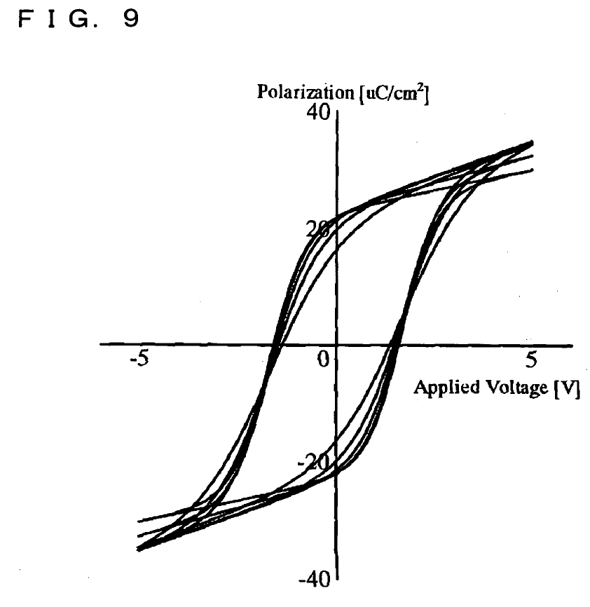

FIG. 8 and FIG. 9 show the hysteresis curves at five random points of Sample E and Sample F, respectively. It was found that while the hysteresis characteristic of Sample E, in which the PZT solution (Solution Z in Example 2) was homogeneously applied in plane, has a distribution in the plane, the hysteresis characteristic of Sample F, having a distribution of Solution X and Solution Y, is uniform in the plane.

1. A method for making a ferroelectric thin film used in a ferroelectric device including a ferroelectric capacitor having an upper electrode, a ferroelectric thin film, and a lower electrode, comprising discharging at least two stock solutions in an inkjetting process through separate inkjet heads of an apparatus having at least two inkjet heads to apply the stock solutions.

2. A method for making a ferroelectric thin film according to claim 1, wherein the stock solutions are a ferroelectric solution and a paraelectric solution.

3. A method for making a ferroelectric thin film according to claim 1, wherein the stock solutions are ferroelectric solutions having different composition ratios.

4. A method for making a ferroelectric thin film according to any one of claim 1 to claim 3, wherein the discharge amount of each of the stock solutions is changed to generate a distribution of the composition over the thickness of the thin film.

5. A method for making a ferroelectric thin film according to any one of claim 1 to claim 3, wherein the discharge amount of each of the stock solutions is changed to generate a distribution of the composition in a plane.

6. A method for making a ferroelectric thin film according to any one of claim 1 to claim 3, wherein a hydrophilic treatment is performed on a substrate before the application of the stock solutions with the inkjetting process.

7. A method for making a ferroelectric thin film according to any one of claim 1 to claim 3, wherein a water-repelling treatment is performed on a substrate before applying the stock solutions with the inkjetting process.

8. A method for making a ferroelectric thin film according to any one of claim 1 to claim 3, wherein a discharging time interval in the inkjetting process is set so that a next landing of the stock solution discharged in the inkjetting process occurs sufficiently earlier than drying of the previous landing.

9. A method for making a ferroelectric thin film according to any one of claim 1 to claim 3, wherein a discharging time interval in the inkjetting process is set so that a next landing of the stock solution discharged in the inkjetting process occurs after the previous landing has completely dried.

10. A method for making a ferroelectric thin film according to claim 1 or claim 2, wherein the ferroelectric solution and the paraelectric solution are applied so as to each have a distribution in the ferroelectric thin film.
